(19) United States
(12) Patent Application Publication
(10) Pub. No.: US 2025/0321884 A1
(43) Pub. Date: Oct. 16, 2025

(54) MEMORY SYSTEMS, METHODS AND STORAGE MEDIUMS

(71) Applicant: YANGTZE MEMORY TECHNOLOGIES CO., LTD., Wuhan (CN)

(72) Inventors: Zhuangfei QIAN, Wuhan (CN); Weilin LIU, Wuhan (CN); Zhe SUN, Wuhan (CN); Haojiang XU, Wuhan (CN); Hua TAN, Wuhan (CN)

(21) Appl. No.: 19/169,838

(22) Filed: Apr. 3, 2025

(30) Foreign Application Priority Data
Apr. 12, 2024 (CN) 202410447156.8

(51) Int. Cl. G06F 12/02

(52) U.S. Cl. CPC G06F 12/0246; G06F 2212/7202

(57) ABSTRACT

Implementations of the present disclosure provide memory systems, methods of operating thereof and readable storage mediums. An example memory system includes a memory device and a memory controller. The memory device includes selected dies each including memory planes. A memory plane to be operated in the memory planes serves as a first memory plane. The memory controller is configured to acquire a number of the first memory plane in each selected die, acquire a priority of each selected die, determine at least one target die from the selected dies according to the number of the first memory plane and the priority of each selected die, and send a first operation command to the memory device to indicate the at least one target die to execute corresponding operations on the first memory plane contained therein.

### CROSS-REFERENCE TO RELATED APPLICATIONS

The present application claims the benefit of priority to China Application No. 202410447156.8, filed on Apr. 12, 2024, the content of which is incorporated herein by reference in its entirety.

### TECHNICAL FIELD

Implementations of the present disclosure relate to semiconductor technology field, for example, memory systems, methods of operating thereof and readable storage mediums.

### BACKGROUND

Memory devices are storage devices for storing information in modern information technology. Some semiconductor memories such as non-volatile memory have gradually become the mainstream product in the memory market due to its high storage density, controllable production cost, suitable programing and erasing speeds and retention characteristics. However, with the continuously increasing demands for memory devices, there are many spaces for improvements for memory devices and systems thereof.

### SUMMARY

According to some aspects of the implementations of the present disclosure, there is provided a memory system including a memory device and a memory controller coupled therewith. The memory device including a plurality of selected dies, each of the selected dies including a plurality of memory planes. The memory planes to be operated in the plurality of memory planes serves as first memory planes. The plurality of selected dies are at least a plurality of dies among all dies of the memory device. The memory controller is configured to: acquire the number of the first memory plane in each selected die; acquire a priority of each selected die; determine at least one target die from the plurality of selected dies according to each of the numbers and each of the priorities; and send a first operation command to the memory device. The first operation command instructs the target dies to execute corresponding operations on the first memory planes contained therein.

In some implementations, the memory controller is further configured to sum the number of the first memory plane and a value of the priority contained in each selected die to get an enable factor; and select the selected dies with larger enable factors as target dies according to an order from large to small of the plurality of enable factors.

In some implementations, the memory controller is further configured to arbitrarily determine at least one selected die from a plurality of selected dies with equal enable factors as the target dies in response to a plurality of equal enable factors.

In some implementations, the memory device is configured to receive the first operation command and execute corresponding operations on the first memory planes in the target dies in response to the first operation command.

In some implementations, the memory controller is further configured to acquire a bit mapping table of the selected dies and determine the number of bits on which the bit information is the first information according to the bit mapping table. Each bit in the bit mapping table corresponding to one memory plane in the plurality of memory planes and a bit information on the bit indicating whether the memory plane is a first memory plane. The number of bits on which the bit information is the first information is the number of the first memory planes in the plurality of memory planes.

In some implementations, the memory controller is further configured to reduce the priority of the at least one target die in response to the target dies having executed corresponding operations on the first memory planes contained therein.

In some implementations, the memory controller is further configured to record a duration for which operation is not executed on each selected die in the plurality of selected dies; and increase the priority of a selected die by at least one in response to the idle duration of the selected die is greater than or equal to a preset duration.

In some implementations, the memory controller is further configured to determine a maximum number of the target dies according to the peak power consumption allowed currently by the memory system.

In some implementations, the memory planes without operations to be executed in the plurality of memory planes serve as second memory planes; and the memory controller is further configured to: acquire the number of the second memory plane in each selected die; and adjust the priority of the selected die corresponding to zero second memory plane to an initial priority in response to the number of the second memory plane being zero; a value of the initial priority being a set value acquired upon powering up the memory system.

In some implementations, the value of the initial priority is 0.

In some implementations, the memory device is configured to execute asynchronous multi-plane independent AMPI read operation on the first memory planes in the target dies in response to the first operation command.

According to the some aspects of the implementations of the present disclosure, there is provided a method of operating a memory system, including acquiring the number of the first memory plane in each selected die and acquiring a priority of each selected die and determining at least one target die from the plurality of selected dies according to each of the numbers and each of the priorities. The memory planes to be operated in each selected die serves as first memory planes. The method may further include sending a first operation command to the memory device by the memory controller. The first operation command instructs the target dies to execute corresponding operations on the first memory planes contained therein.

In some implementations, the determining at least one target die from the plurality of selected dies according to each of the numbers and each of the priorities includes: summing the number of the first memory plane and a value of the priority contained in each selected die to get an enable factor; and selecting the selected dies with larger enable factors as the target dies according to an order from large to small of the plurality of enable factors.

In some implementations, the method further includes: arbitrarily determining at least one die from a plurality of selected dies with equal enable factors as the target dies in response to a plurality of equal enable factors.

In some implementations, the method further includes: receiving, by the memory device, the first operation command and executing corresponding operations on the first memory planes in the target dies in response to the first operation command.

In some implementations, the acquiring the number of the first memory plane in each selected die includes acquiring a bit mapping table of the selected dies and determining the number of bits on which the bit information is a first information according to the bit mapping table. Each bit in the bit mapping table corresponding to one memory plane in the plurality of memory planes and a bit information on the bit indicating whether the memory plane is a first memory plane. The number of bits on which the bit information is the first information is the number of the first memory plane in the plurality of memory planes.

In some implementations, the method further includes: reducing the priority of the at least one target die in response to the target dies having executed corresponding operations on the first memory planes contained therein.

In some implementations, the method further includes: recording a duration for which operation is not executed on each selected die in the plurality of selected dies; and increasing the priority of a selected die by at least one in response to the duration for which no operation is executed on the selected die is greater than or equal to a preset duration.

In some implementations, the method further includes: determining a maximum number of the target dies according to the peak power consumption allowed currently by the memory system.

In some implementations, the memory planes without operations to be executed in the plurality of memory planes serve as second memory planes. The method further includes: acquiring the number of the second memory plane in each selected die; and adjusting the priority of the selected die corresponding to zero second memory plane to an initial priority in response to the number of the second memory plane being zero. A value of the initial priority being a set value acquired upon powering up the memory system.

In some implementations, the value of the initial priority is 0.

In some implementations, the method further includes: executing, by the memory device, asynchronous multi-plane independent AMPI read operation on the first memory planes in the target dies in response to the first operation command.

According to some aspects of an implementation of the present application, there is provided a readable storage medium storing therein a computer program that, when it is executed, implements the method.

### BRIEF DESCRIPTION OF THE DRAWINGS

FIG. 1 is a structure diagram according to an example implementation;

FIG. 2A is a diagram of example memory card according to an implementation of the present disclosure;

FIG. 2B is a diagram of an example solid state drive according to an implementation of the present disclosure;

FIG. 3 is a diagram of example memory device according to an implementation of the present disclosure;

FIG. 4 is an example sectional diagram of a memory cell array according to an implementation of the present disclosure;

FIG. 5 is a diagram of another example memory device according to an implementation of the present disclosure;

FIG. 6 is a diagram of example memory system according to an implementation of the present disclosure;

FIG. 7 is a diagram of another example memory device according to an implementation of the present disclosure;

FIG. 8 is a diagram of example die according to an implementation of the present disclosure;

FIG. 9 is a diagram of multi-dies priorities labeling according to an implementation of the present disclosure; and

FIG. 10 is a diagram of a method of operating a memory system according to an implementation of the present disclosure.

### DETAILED DESCRIPTION

Example implementations of the present disclosure will be described in greater detail below with reference to the accompanying drawings. Although example implementations of the present disclosure are shown in drawings, it is to be appreciated that the present disclosure may be implemented in various forms rather than being limited to the specific implementations as set forth herein. In contrast, these implementations are provided to understand the present disclosure more thoroughly and convey the scope of the present disclosure completely to those skilled in the art.

In the following description, specific details are presented to provide thorough understanding of the present disclosure. However, it is obvious to those skilled in the art that the present disclosure may be implemented without one or more of these details. In other examples, in order to avoid confusion with the present disclosure, some technical features well known in the art are not described. That is, not all features of the practical implementations are described herein, and well-known functions and structures are not described.

It should be understood that when an element or a layer is said to be “on”, “adjacent to”, “connected to” or “coupled to” other elements or layers, it may be directly on, adjacent to, connected to or coupled to other elements or layers, or there may be intervening elements or layers. To the contrary, when an element is said to be “directly on”, “directly adjacent to”, “directly connected to” or “directly coupled to” other elements or layers, there are no intervening elements or layers.

Terms are used herein only for describing specific implementations rather than limiting the present disclosure. As used herein, the singular form “a”, “an” and “the” are also intended to include the plural form unless otherwise stated in the context. It is also understood that when used in the description, terms “consist” and/or “include” confirm the presence of said features, integers, steps, operations, elements and/or components, but do not exclude the presence or addition of one or more other features, integers, steps, operations, elements and/or components. As used herein, the term “and/or” includes any and all combinations of relevant listed items.

It should be understood that “some implementations” or “an implementation” as mentioned throughout the description means that particular features, structures, or characteristics related to the implementation are included in at least one implementation of the present disclosure. Therefore, “in some implementations” or “in an implementation” occurring throughout the description does not necessarily refer to the same implementation. In addition, these particular features, structures, or characteristics may be incorporated in one or more implementations in any suitable manners. It should be understood that in various implementations of the present disclosure, the sequence numbers of the above-described processes do not mean the sequential order of executions. The execution order of the processes should be determined by their functions and internal logics and should not limit the implementation process of the implementations of the present disclosure.

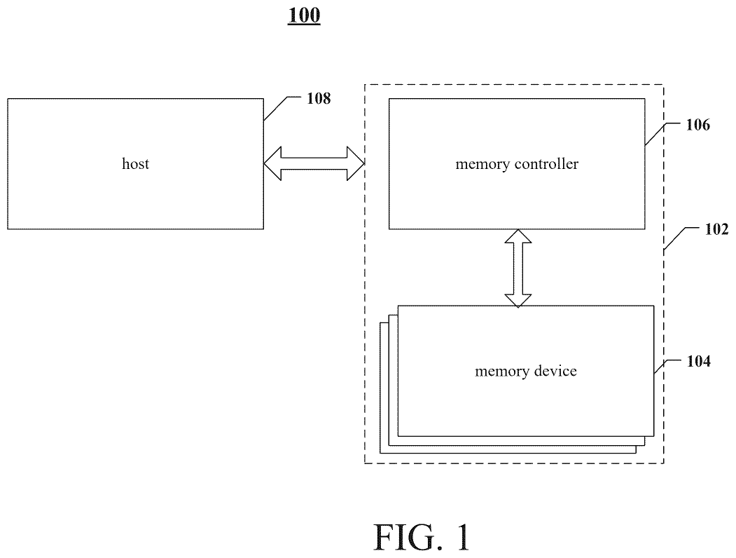

FIG. 1 illustrates a block diagram of an example system 100 having a memory device according to some aspects of the present disclosure. The system 100 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having memories therein. As shown in FIG. 1, system 100 may include a host 108 and a memory system 102 having one or more memory devices 104 and a memory controller 106. The host 108 can be a processor of an electronic device, such as a central processing unit (CPU), or a system-on-chip (SoC), such as an application processor (AP). The host 108 may be configured to send data to the memory device 104 or receive data from the memory device 104. The memory device 104 according to an implementation of the present disclosure may include, but not limited to a 2D or 3D NAND (Not-AND) memory or NOR memory, ferroelectric random access memory (FRAM), a magnetic random access memory (MRAM), a phase-change memory (PCM), a resistive random access memory (RRAM) etc. According to some implementations, the memory controller 106 is coupled to the memory device 104 and the host 108 and is configured to control the memory device 104. The memory controller 106 can manage the data stored in the memory device 104 and communicate with the host 108. In some implementations, the memory controller 106 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, the memory controller 106 is designed to operate in high duty cycle environment SSDs or embedded multimedia cards (eMMCs) used as data storage for mobile devices, such as smart phones, tablet computers and laptop computers, etc., and enterprise memory arrays.

The memory controller 106 can be configured to control operations of the memory device 104, such as read, erase, and program operations. The memory controller 106 can also be configured to manage various functions with respect to the data stored or to be stored in the memory device 104 including, but not limited to bad-block management, garbage collection, logical-to-physical address conversion, wear leveling, etc. In some implementations, the memory controller 106 is further configured to process error correction codes (ECCs) with respect to the data read from or written to the memory device 104. Any other suitable functions may be performed by the memory controller 106 as well, for example, formatting the memory device 104. The memory controller 106 can communicate with an external device (e.g., the host 108) according to a particular communication protocol. For example, the memory controller 106 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

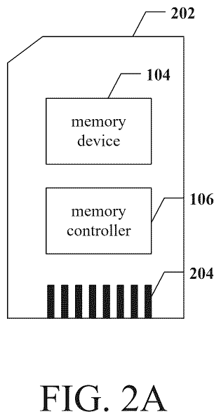

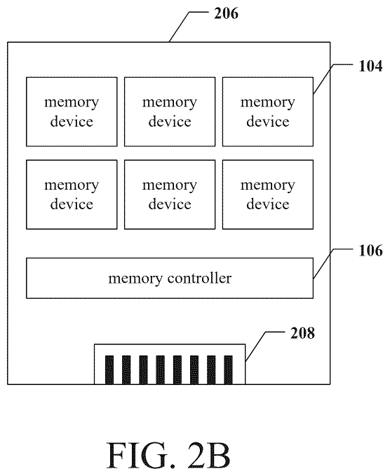

Memory controller 106 and one or more memory devices 104 can be integrated into various types of storage apparatuses, for example, be included in the same package, such as a universal Flash storage (UFS) package or an eMMC package. That is, the memory system 102 can be implemented and packaged into different types of end electronic products. In an example as shown in FIG. 2A, the memory controller 106 and a single memory device 104 can be integrated into a memory card 202. The memory card 202 may include a PC card (PCMCIA, Personal Computer Memory Card International Association), a CF card, a smart media (SM) card, a memory stick, a multimedia card (MMC, RS-MMC, MMCmicro), a SD card (SD, miniSD, microSD, SDHC), a UFS etc. The memory card 202 may also include a memory card connector 204 coupling the memory card 202 and the host (e.g., the host 108 in FIG. 1). In another example as shown in FIG. 2B, the memory controller 106 and the plurality of memory devices 104 may be integrated into a SSD 206. The SSD 206 may also include a SSD connector 208 coupling the SSD 206 and the host (e.g., the host 108 in FIG. 1). In some implementations, the storage capacity and/or the operation speed of the SSD 206 is greater than those of the memory card 202.

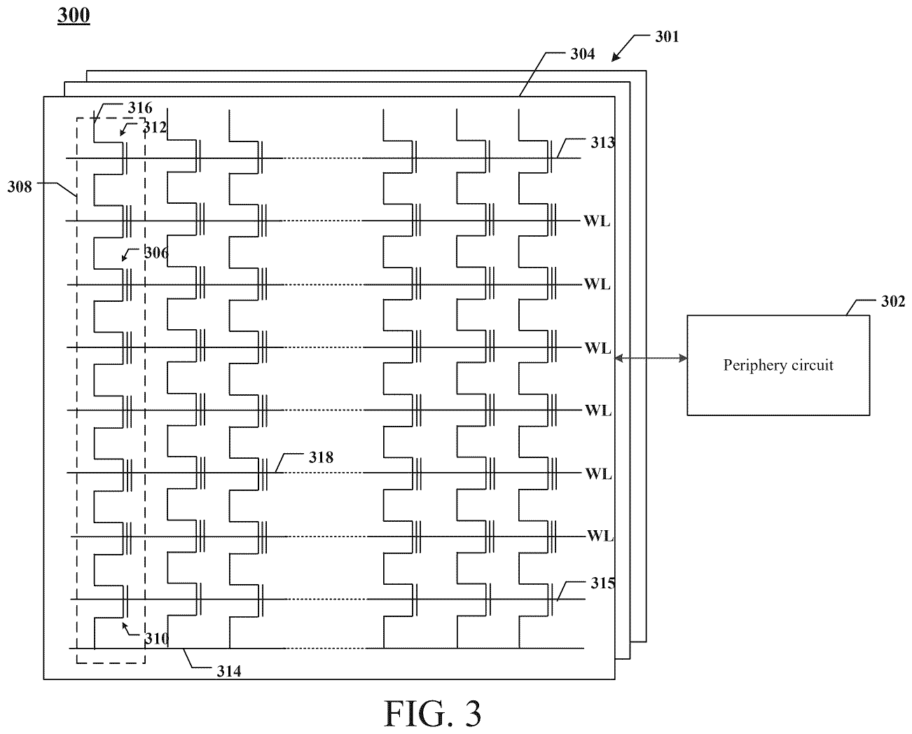

FIG. 3 shows a schematic circuit diagram of example memory device 300 including a peripheral circuit according to some aspects of the present disclosure. The memory device 300 may be an example of the memory device 104 in FIG. 1. The memory device 300 may include a memory cell array 301 and a peripheral circuit 302 coupled to the memory cell array 301. A memory cell array 301 being a 3D NAND memory cell array will be described as an example in which the memory cells 306 are provided in form of an array of NAND memory strings 308 and each NAND memory string 308 extends vertically over the substrate (not shown). In some implementations, each NAND memory string 308 includes a plurality of memory cells 306 coupled in series and stacked vertically. Each memory cell 306 can remain continuous analog values, for example, voltages or charges, depending on the number of electrons trapped in the region of the memory cell 306. Each memory cell 306 may be a memory cell of a floating-gate type that includes floating-gate transistors or a memory cell of a charge trapping type that includes charge trapping transistors.

In some implementations, each memory cell 306 is a single-level cell (SLC) that has two possible memory states and can therefore store one bit of data. For example, the first memory state “0” may correspond to the first voltage range, and the second memory state “1” may correspond to the second voltage range. In some implementations, each memory cell 306 is a multiple-level cell (MLC) that can store more than one bit of data in more than four memory states. For example, an MLC may store two bits per cell, three bits per cell (also known as TLC) or four bits per cell (also known as QLC), etc. Each MLC may be programmed to assume a range of possible nominal storage values. In an example, if each MLC stores two bits of data, the MLC may be programmed to write one of three possible nominal storage values into the cell, and the fourth nominal storage value other than the three ones may be used to indicate the erase state.

As shown in FIG. 3, each NAND memory string 308 may include a bottom select gate (BSG) 310 at its source and a top select gate (TSG) 312 at its drain. BSG 310 and TSG 312 may be configured to activate selected NAND memory strings 308 during reading and programming operations. In some implementations, sources of the NAND memory strings 308 in the same memory block 304 are coupled together through a same source line (SL) 314 (e.g., the common SL). In other words, according to some implementations, all NAND memory strings 308 in the same memory block 304 have an array common source (ACS). According to some implementations, TSG 312 of each NAND memory string 308 is coupled to a corresponding bit line (BL) 316 and data may be read from or written into the bit line 316 via an output bus (not shown). In some implementations, each NAND memory string 308 is configured to be selected or deselected by applying a select voltage (for example higher than the threshold voltage of the transistor having TSG 312) or a deselect voltage (for example, 0V) to the corresponding TSG 312 via one or more TSG lines 313 and/or applying a select voltage (for example higher than the threshold voltage of the transistor having BSG 310) or a deselect voltage (for example, 0V) to the corresponding BSG 310 via one or more GSG lines 315.

As shown in FIG. 3, the NAND memory string 308 may be organized into a plurality of memory blocks 304 and each of the plurality of memory blocks 304 may have a common source line 314 (for example, coupled to ground). In some implementations, each memory block 304 is the basic data unit for erase operation. That is, all memory cells 306 on a same memory block 304 are erased at the same time. In order to erase the memory cells 306 in a selected memory block, it is possible to bias the source line 314 coupled to the selected memory block and the unselected memory blocks in the same plane as the selected memory block with an erase voltage (Vers) (for example, a high positive voltage such as 20V or higher). It will be appreciated that in some examples, it is possible to execute erase operation on the semi-memory block level, the quarter-memory block level or a level of any suitable number of memory blocks or any suitable fraction of a memory block. Memory cells 306 in adjacent NAND memory strings 308 may be coupled via the word line 318 that chooses which row of the memory cells 306 is subject to the reading and programming operations.

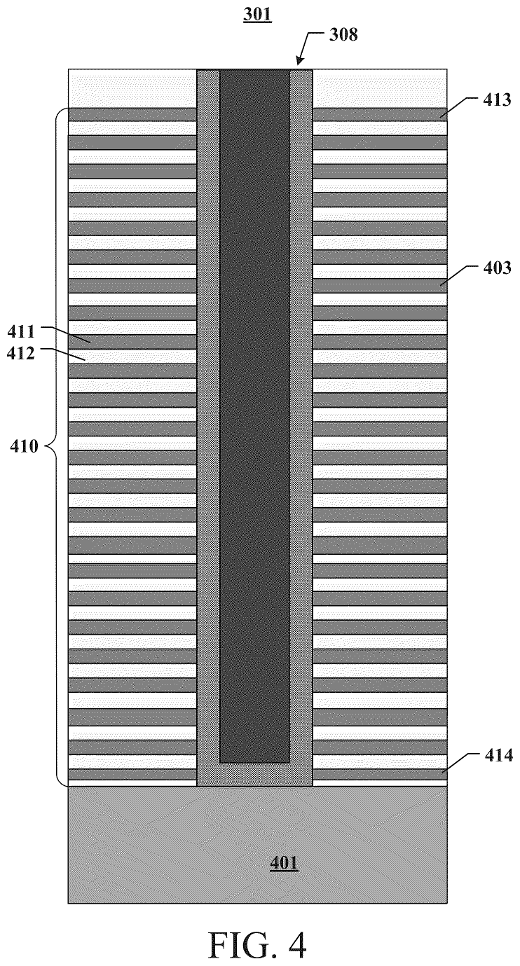

FIG. 4 shows a sectional diagram of an example memory cell array 301 including NAND memory strings 308 according to some aspects of the present disclosure. As shown in FIG. 4, a NAND memory string 308 may include a stack 410 including a plurality of gate layers 411 and a plurality of insulating layers 412 stacked alternatively and the memory string 308 penetrating through the gate layers 411 and the insulating layers 412 vertically. The gate layers 411 and the insulating layers 412 may be stacked alternatively and adjacent two gate layers 411 are separated by an insulating layer 412. The number of the pairs of gate layers 411 and insulating layers 412 in the stack 410 may determine the number of the memory cells included in the memory cell array 301.

The material for the gate layer 411 may include conductive materials. Conductive materials include, but not limited to tungsten (W), cobalt (Co), copper (Cu), aluminum (Al), polysilicon, doped silicon, silicide or any combination thereof. In some implementations, each gate layer 411 includes a metal layer such as a tungsten layer. In some implementations, each gate layer 411 includes a doped polysilicon layer. Each gate layer 411 may include a control gate surrounding the memory cells. The gate layer 411 at the top of the stack 410 may extend laterally as a top select gate line, the gate layer 411 at the bottom of the stack 410 may extend laterally as a bottom select gate line, and the gate layers 411 extending laterally between the top select gate line and the bottom select gate line may serve as word line layers.

In some implementations, the stack 410 may be disposed on the substrate 401. The substrate 401 may include silicon (e.g., single crystalline silicon), silicon germanium (SiGe), gallium arsenide (GaAs), germanium (Ge), silicon-on-insulator (SOI), germanium-on-insulator (GOI) or any other suitable material.

In some implementations, the NAND memory string 308 includes a channel structure extends vertically through the stack 410. In some implementations, the channel structure includes a channel hole filled with semiconductor material(s) (e.g., serving as the semiconductor channel) and dielectric material(s) (e.g., serving as the memory film). In some implementations, the semiconductor channel includes silicon, such as polysilicon. In some implementations, the memory film is a composite dielectric layer including a tunneling layer, a storage layer (also known as “charge trapping/storage layer”) and a barrier layer. The channel structure may have a cylindrical shape (e.g., a pillar shape). According to some implementations, the semiconductor channel, the tunneling layer, the storage layer and the barrier layer are arranged radially from the center of the pillar towards the outer surface in this order. The tunneling layer may include silicon oxide, silicon oxynitride or any combination thereof. The storage layer may include silicon nitride, silicon oxynitride or any combination thereof. The barrier layer may include silicon oxide, silicon oxynitride, high dielectric constant (high-k) dielectric or any combination thereof. In an example, the memory film may include a composite layer of silicon oxide/silicon oxynitride/silicon oxide (ONO).

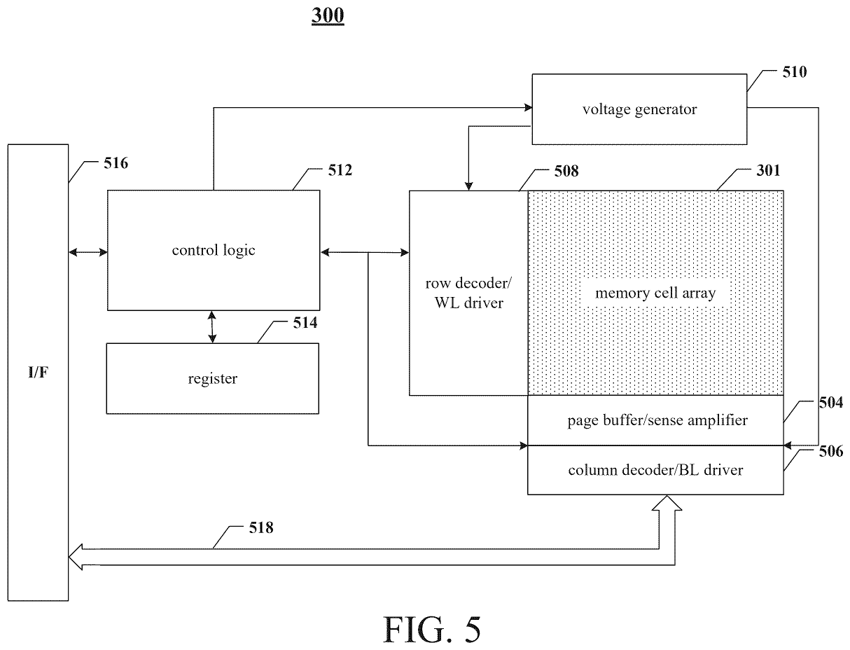

Referring back to FIG. 3, the peripheral circuit 302 may be coupled to the memory cell array 301 through the bit line 316, the word line 318, the source line 314, the BSG line 515 and the TSG line 313. The peripheral circuit 302 may include any suitable analog, digital and hybrid signal circuits for facilitating operation of the memory cell array 301 by applying voltage signals and/or current signals to each target memory cell 306 via bit line 316, word line 318, source line 314, BSG line 315 and TSG line 313 and sensing voltage signals and/or current signals from each target memory cell 306. The peripheral circuit 302 may include various types of peripheral circuits formed by metal-oxide-semiconductor (MOS) technology. As an example, FIG. 5 shows some example peripheral circuits. The peripheral circuit 302 includes a page buffer/sense amplifier 504, a column decoder/bit line driver 506, a row decoder/word line driver 508, a voltage generator 510, a control logic 512, a register 514, an interface 516 and a data bus 518. In some examples, additional peripheral circuits not shown in FIG. 5 may be further included.

The page buffer/sense amplifier 504 may be configured to read and program (write) data from/to the memory cell array 301 according to control signals from control logic 512. In an example, the page buffer/sense amplifier 504 may store programming data (writing data) to be programed into the memory cell array 301. In another example, the page buffer/sense amplifier 504 may execute the programming verification operation to ensure that the data has been properly programed into the memory cells 306 coupled to the selected word line 318. In yet another example, the page buffer/sense amplifier 504 may also sense a low-power signal from a bit line 316 indicating the data bit stored in a memory cell 306 and amplify the small voltage swing to an identifiable logic level in the read operation. The column decoder/bit line driver 506 may be configured to be controlled by the control logic 512 and select one or more NAND memory strings 308 by applying a bit line voltage generated by the voltage generator 510.

The row decoder/word line driver 508 may be configured to be controlled by the control logic 512, and select/deselect memory blocks 304 of the memory cell array 301 and select/deselect word lines 318 of the memory block 304. The row decoder/word line driver 508 may be further configured to drive word lines 318 using word line voltages generated by the voltage generator 510. In some implementations, the row decoder/word line driver 508 may also select/deselect and drive BSG line 315 and TSG line 313. As detailed in the following, the row decoder/word line driver 508 is configured to execute programming operation on the memory cells 306 coupled to the selected word line(s) 318. The voltage generator 510 may be configured to be controlled by the control logic 512 and generate the word line voltage (for example, read voltage, program voltage, pass voltage, channel boost voltage, verification voltage, etc.), the bit line voltage and the source line voltage to be provided to the memory cell array 301.

The control logic 512 may be coupled to each of the peripheral circuits described above and configured to control operations of each of the peripheral circuits. The register 514 may be coupled to the control logic 512 and include a status register, a command register and an address register to store status information, command operation codes (OP codes) and command addresses for controlling operations of each of the peripheral circuits. The interface 516 may be coupled to the control logic 512, and serve as a control buffer to buffer control commands received from the host (not shown) and relay them to the control logic 512, and buffer status information received from the control logic 512 and relay them to the host. The interface 516 may be further coupled to the column decoder/bit line driver 506 via the data bus 518 and serve as a data I/O interface and a data buffer to buffer data and relay it to the memory cell array 301 or relay or buffer data from the memory cell array 301.

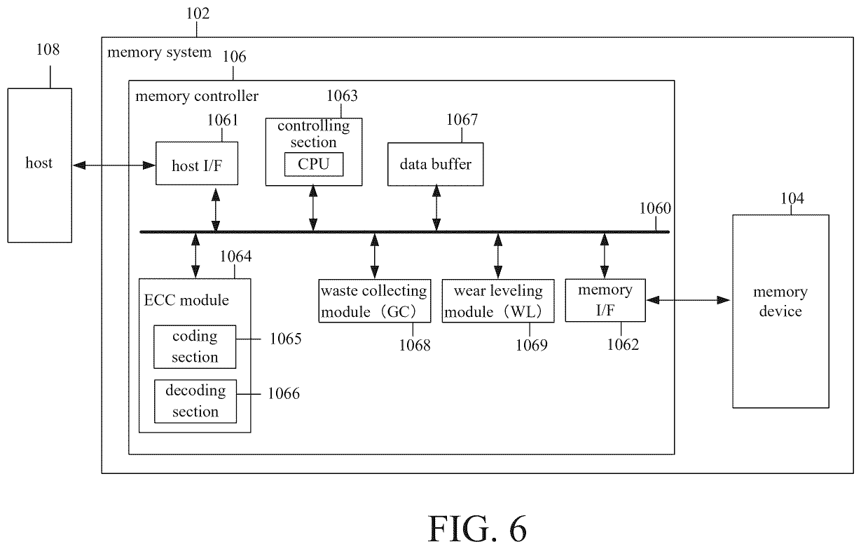

FIG. 6 provides a block diagram of a memory controller 106 applied to a memory system 102. As shown in FIG. 6, the memory system 102 includes a memory controller 106 and a memory device 104 which may be coupled with each other in any suitable way. In implementations of the present disclosure, the memory controller 106 may include a host I/F 1061, a memory I/F 1062, a controlling section 1063, an error correction code (ECC) module 1064, a data buffer 1067, a waste collecting module 1068, a wear-leveling module 1069 and an internal bus 1060. The ECC module 1064 includes a coding section 1065 and a decoding section 1066. The host I/F 1061 outputs the commands, user data (written data) received from the host 108 to the internal bus 1060 and sends user data (read data) read from the memory device 104 and responses from the controlling section 1063 to the host 108. The memory controller 106 may further includes a ROM and a RAM. The ROM stores firmware or firmware program codes for the memory controller 106 for initializing and operating components of the memory controller 106 and the RAM may be generally configured to buffer data.

The memory I/F 1062 controls the processing of writing user data to memory device 104 and processing of reading the memory device 104 based on instructions from the controlling section 1063. The controlling section 1063 controls the memory system 102 as a whole and is for example a central processor (CPU), a microprocessor (MPU) etc. The controlling section 1063 performs controlling according to a command in case of receiving the command from the host 108 via the host I/F 1061. For example, the controlling section 1063 instructs the memory I/F 1062 to write user data and parity check to the memory device 104 according to commands from the host 108. Furthermore, the controlling section 1063 instructs the memory I/F 1062 to program memory cells by the memory device 104 according to commands from the host 108 and the memory device 104 to updates the physical address-logical address mapping table after completing programming operation and feeds back the table to the data buffer 1067 for storage via the memory I/F 1062. Alternatively, the controlling section 1063 instructs the memory I/F 1062 to read user data and parity check from the memory device 104 according to commands from the host 108. In response to operation demands, the controlling section 103 may access the DRAM built in the memory system 102 to get the logical address-physical address mapping table and control the memory device 104 to implement operations on memory cells at related addresses according to address information. For operations such as data erase or data write, the controlling section 103 will further update the logical address-physical address mapping table or the memory device 104 updates the mapping table. For a memory system 102 without DRAM, the controlling section 103 may store the mapping table using the memory of the host 108 and access the host's memory to get the mapping table or update the mapping table. Alternatively, the mapping table is a second level mapping table and the first level mapping table is stored in the data buffer 1067 or the RAM of the memory controller 106. The second level mapping table is stored in the memory device 104 and divided into a plurality of regions. The first level mapping table stores physical addresses of regions in the memory device 104.

The ECC module 1064 has a coding section 1065 and a decoding section 1066. The coding section 1065 may code user data of predetermined size written in a same page to generate parity check data. The parity check data may be generated by coding based on programming data. The parity check data is written in the page of the user data that has been written as the basis of coding and the decoding section 1066 decodes using the parity check data. The data buffer 1067 stores temporarily user data received from the host before storing in the memory device 104 and store temporarily data read from the memory device 104 before sending to the host 108.

The waste collecting module 1068 is configured to read, re-write valid data on some memory blocks when the storage space of the memory device reaches a certain threshold and then label these memory blocks to obtain new spare memory blocks. Waste collecting is generally implemented in three steps: selecting source memory blocks having less valid data; finding valid data in the source memory blocks; and writing the valid data to the target memory blocks. At this time, all data in the source memory blocks becomes invalid data and the source memory blocks may be labeled to be new spare memory blocks. The wear leveling module 1069 is configured to balance wears (erasure times) of each memory block in the memory system by data statistics and algorithm. The wear leveling may be generally implemented in two steps: selecting source memory blocks in which cold data resides; reading valid data on the source memory blocks and writing them to memory blocks with a relative large erasure times. At this time, the valid data in the source memory blocks becomes invalid data and is labeled.

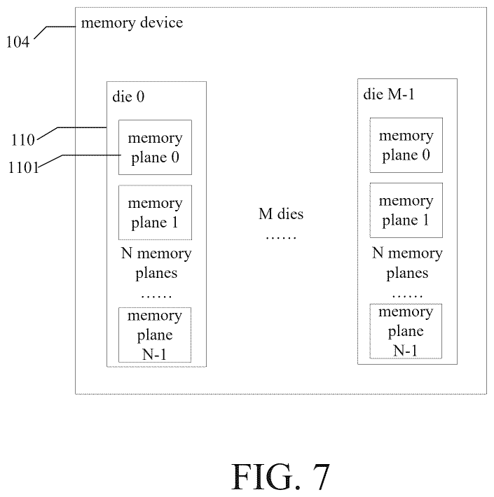

Referring to FIG. 7, the memory device 104 may include a plurality of dies 110, for example, M dies 110. Each die 110 may include N memory planes. Each memory plane 1101 includes memory blocks 304 illustrated in FIG. 3. A die 110 further includes a peripheral circuit that may be coupled with the memory planes 1101. A plurality of memory planes 1101 may constitute a memory cell array inside a die 110. It is noted that the peripheral circuit according to implementations of the present disclosure is an entire device defined for the entire memory array. For each memory plane 1101, there may be a same corresponding partial circuit or they may share partial circuit, which all fall in the entire peripheral circuit. Illustratively, a plurality of memory planes 1101 may be coupled to a peripheral circuit. Alternatively, each memory plane 1101 is coupled with a peripheral circuit, respectively, and the memory controller 106 controls each peripheral circuit to access a respective memory plane. A die 110 is a device structure cut from the wafer and having independent electrical functions. Memory planes 1101 and peripheral circuits in a die 110 may be coupled and secured through hybrid bonding.

In some implementations, in response to operation requests from the host 108, the memory system 102 is accessed and respective operations need to be executed on the memory system 102 such as read, write or erase operation. In response to the operation request from the host 108, when operations need to be executed on a plurality of dies 110 in the M dies 110 of the memory device 104, operations may be executed on the plurality of dies 110 sequentially or simultaneously.

In some implementations, in the synchronous operation, the plurality of memory planes may be mapped as an entire physical address to the logical address of the host 108 to perform reading, programming or erasure operation. When there are operation requests, the memory device 104 may execute them in turn. Considering a read operation as an example, the read operation may be implemented for a page of a memory plane or pages coupled to the same layer of word lines or located on same rows in the plurality of memory planes, and the next read operation is implemented after the current read operation is completed.

In some implementations, in the asynchronous operation, each memory plane may be mapped as an independent physical address to the logical address of the host 108 to perform reading, programming or erasure operation. When there are operation requests, the memory device 104 may perform the operations at the same time and separate operations may be implemented for each memory plane according to different logical address-physical address mapping. Considering read operations as an example, simultaneous read operations may be implemented separately for any page in the plurality of memory planes to improve the response speed of the memory device 104. This kind of read mode may be referred to as an asynchronous multi-plane independent (AMPI) read, which facilitates improving parallel operating efficiency of the memory device 104 and particularly facilitates improving the random read performance of the memory device 104. Programming operations and erasure operations may also be implemented independently for each memory plane.

In some implementations, a die 110 has a plurality of memory planes that are used as the operating objects in the die 110. Taking the die 110 to be operated in FIG. 7 as the selected die 110, the memory plane to be operated in the selected die 110 is denoted as the first memory plane, and the number of selected dies 110 may be M or any number smaller than M. The selected dies 110 are some or all selected from the M dies 110 in FIG. 7. Some or all of the selected dies 110 are selected as target dies. Selected dies 110, target dies and non-selected dies 110 are all different state presentations under different conditions of practical physical dies 101.

Under test conditions that each memory plane has the same amount of data, for example, for read operations with the same amount of data, selected dies 110 in which read operations are executed for more first memory planes have a power consumption smaller than that of the selected dies 110 in which read operations are executed for less first memory planes. In other words, considering one selected die 110 as a reference example, when completing writing or reading with the same amount of data, the more first memory planes for which corresponding operations are executed, the less the power consumption is. A KIOPS (Input/Output Operations Per Second) read test is performed on the die 110. Each memory plane may be read 1000 times per second with 4 kb data read per time. The current (in mA) obtained in die test increases with the increase of the number of memory planes. The test results are transformed into the average power consumption per KIOPS, namely the average power consumption for 1000 readings per second and 4 kb data per reading. The average power consumption decreases with the increase of the number of memory planes. Illustratively, when read test is performed on a memory plane in the die 110, the average power consumption is 3.82 mW/KIOPS. When read test is performed on 6 memory planes, the average power consumption is 1.86 mW/KIOPS. For read tests of the same amount of data, the more memory planes in die 110 are read, the smaller the power consumption is.

In some implementations, when operations are executed in parallel on too many dies 110, the overall power consumption of the memory system 102 will increase, possibly exceeding the peak power consumption allowed by the current memory system 102. At this time, the memory system 102 can reduce the operating frequencies of internal memory devices or pause operations of some dies 110 for the too high power consumption. As long as the peak power consumption of the memory system 102 allows, selecting more dies 110 to execute operations facilitates improving operating speed. It is possible to determine the number of dies 110 that can currently perform operations simultaneously depending on the peak power consumption allowed by the current memory system 102. The dies 110 on which operations are executed may be referred to as target dies 110. Target dies are selected from selected dies 110 that are dies having memory planes to be operated in all dies of the memory device 104. Illustratively, the number of all dies in the memory device 104 is M, and there are N selected dies 110 having memory planes to be operated. At most K dies are selected from the selected dies 110 as the target dies to perform related operations. K≤N≤M, and K is the number of dies 110 that are allowed to be operated by the peak power consumption of the current memory system 102.

In some implementations, the peak power consumption allowed currently by the memory system 102 may be determined depending on the current temperature of the memory system 102. In case of high temperature, the allowed peak power consumption is low to guarantee stable operation of the memory system, and in case of low temperature, the allowed peak power consumption may be high such that operations are executed on more dies 110 to improve the operation speed. The temperature of the memory system 102 may be obtained by the temperature sensing module integrated in the memory system 102 or obtained by the temperature sensing module outside of the memory system 102. Calculation cores such as the memory controller 106 or the host 108 calculates the peak power consumption according to the current temperature. The memory controller 106 obtains K value by calculating according to the current peak power consumption or accessing a mapping table in which peak power consumptions correspond to the number of target dies. Since the number of dies 110 on which operations are allowed to be operated in the memory system 102 is limited, there might be a case in which not all dies 110 to be operated currently can be selected as target dies for operations, and the dies 110 with higher priorities may be prioritized to perform corresponding operations. With the memory system 102 provided in implementations of the present disclosure, as many as possible dies 110 are selected to perform operations if the power consumption allows, and dies 110 with higher priorities are selected to perform operations in time while dies 110 with lower priorities will not be laid up for a long time either.

According to some aspects of an implementation of the present disclosure, there is provided a memory system including a memory device 104 and a memory controller 106 coupled therewith. The memory device 104 includes a plurality of selected dies 110. Each selected die 110 includes a plurality of memory planes. The memory planes to be operated in the plurality of memory planes serves as first memory planes. The plurality of selected dies 110 are at least a plurality of dies in all dies 110 of the memory device 104. The memory controller 106 is configured to acquire the number of the first memory plane in each selected die 110, acquire a priority of each selected die 110, determine at least one target die from the plurality of selected dies 110 according to each number and each priority, and send a first operation command to the memory device 104. The first operation command instructs the target dies to execute corresponding operations on the first planes contained therein.

In some implementations, the selected dies 110 may be some or all of the all physical dies 110 contained in the memory device 104. When the number of all dies 110 contained in the memory device 104 is small, it is possible to take all dies 110 as selected dies 110 for subsequent priority setting. When the number of all dies 110 contained in the memory device 104 is large, it is possible to take dies 110 having the first memory plane in all dies 110 as selected dies 110 for subsequent priority setting. An upper limit may be set for the number of selected dies 110 in implementations of the present disclosure, the selected dies 110 may include dies 110 having the first memory plane, and may also include dies 110 without the first memory plane. For selected dies 110 without the first memory plane but just having the second memory plane, it is possible to set their priority as the lowest priority and the second memory plane is the memory plane without operations to be executed.

In some implementations, the memory controller 106 is further configured to: acquire a bit mapping table of the selected dies 110, each bit in the bit mapping table corresponding to one memory plane 1101 among the plurality of memory planes 1101 and bit information on the bit indicating whether the memory plane 1101 is a first memory plane; and determine the number of bits on which bit information is first information according to the bit mapping table. The number of bits on which bit information is first information is the number of first memory planes among the plurality of memory planes 1101.

In some implementations, the memory controller 106 acquires address information of corresponding operation to be executed in the memory device 104 in response to the access demand from the host 108 and according to relevant access demand information or instruction. The address information may include the address of the die 110 on which operation needs to be executed and addresses of the first memory plane and the second memory plane in the die 110, and may also include the address of the die 110 on which no operation needs to be executed. For each die 110, the die 110 may be labeled according to whether operations need to be executed on memory planes therein, and it is possible to characterize a first memory plane with a first information, characterize a second memory plane with a second information, the first information may include bit 1 and the second information may include bit 0. Summing the number of bits 1 may obtain the number of first memory planes in a die 110, and summing the number of bits 0 may obtain the number of second memory planes in a die 110.

According to the first information and the second information of each die 110 or selected dies 110, it is possible to create the bit mapping table by the memory controller 106 according to the operation request information from the host 108. The bit mapping table is updated according to the address information executed currently after executing operations on the memory device 104. The operation of updating bit mapping table may be carried out by the peripheral circuit of the memory device 104 and the updated bit mapping table may be sent to the memory controller 106. The operation of updating bit mapping table may also be carried out by the memory controller 106 according to the operation data of the memory device 104.

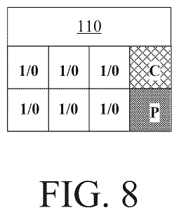

In some implementations, FIG. 8 shows an example priority setting of die 110. The die 110 may include 6 memory planes and P represents priority of the die 110. The priority may include, but not limited to −2, −1, 0, 1, 2, and the larger the value of the priority is, the higher the priority is. Bitmap is the bit distribution of “1” for first memory planes and “0” for second memory planes in the die 110, and C is the sum of 1 and 0 in Bitmap, Die counter, which may characterize the number of first memory planes. It is noted that when the first memory plane and the second memory plane are characterized as other bits, the sum may not be the number of first memory planes and the numbers of first memory planes and second memory planes need to be calculated separately. The numbers of first memory planes and second memory planes may be not limited to the bit mapping table and bit information corresponding to the memory planes. The memory controller 106 acquires the addresses of selected dies 110 to be operated and address information of first memory planes and second memory planes in selected dies 110 in response to the operation request information from the host 108 and may obtain the numbers of first memory planes and/or second memory planes according to the address information.

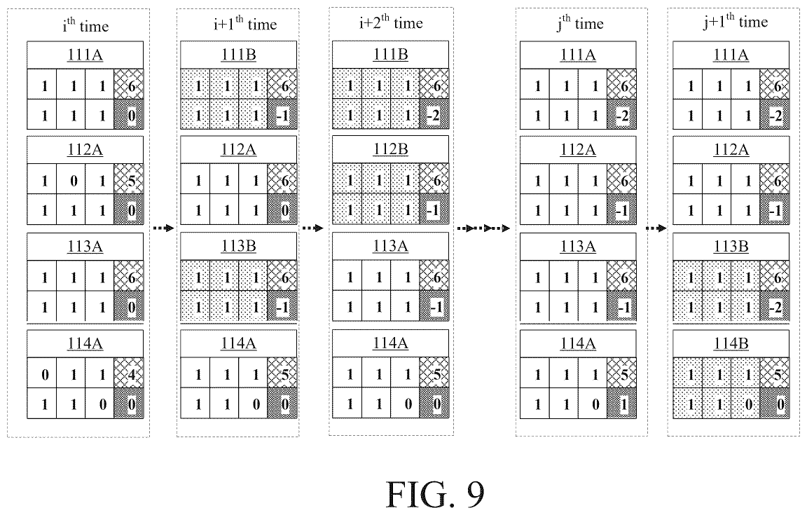

In some implementations, dies 110 having the first memory plane are an example of selected dies 110 in implementations of the present disclosure, and selected dies 110 may not include dies without operations to be executed, that is, C of selected dies is not 0. Referring to FIG. 9, 4 selected dies are illustrated as an example, in which each selected die may include 6 memory planes with bit information of the first memory plane being 1 and bit information of the second memory plane being 0. More selected dies are possible in implementations of the present disclosure. As shown in FIG. 9, there are a first selected die 111, a second selected die 112, a third selected die 113 and a fourth selected die 114. Priority setting operation for the selected dies is illustrated as an example. The i^{th} may be the first priority setting before the first operation on the die. Priorities may be all set as the initial priority 0 or any priority setting.

The operation request from the host 108 may be a command set having queue depths of several sizes. The command set may include a plurality of operation commands. A command set corresponds to operations on the memory planes and each operation corresponds to a setting or updating of priority. Memory systems 102 meeting different protocols may have different queue depths, for example, 1-32 for UFS protocol. Considering 32 as an example, in response to 32 operation commands, it is possible to implement 32 operations on a selected die and update the priority of the selected die after each operation. Before executing the first operation of the current command, it is possible to label the priorities of all selected dies as the initial priority 0. After all operations are completed, the memory planes of selected dies are all second memory planes.

Specifically, in FIG. 9, considering an example in which the ii time is the state of selected die before the first operation, 2 dies from the first selected die 111, the second selected die 112, the third selected die 113 and the fourth selected die 114 are selected as target dies for operations. For example, AMPI read operations are executed on all first memory planes of the 2 target dies. The peak power of the memory system 102 under current conditions allows at most 2 dies to operate. The target dies may be selected according to the number of the first memory plane and the priority of selected die. For example, it is possible to select the selected dies with more first memory planes as target dies to implement operations and select the selected dies with higher priorities as target dies to implement operations.

The memory controller 106 sends a first operation command including the address information of target dies to the memory device 104 after selecting target dies to be operated. The first operation command may instruct to implement related operations on first memory planes in the target dies, including, but not limited to read operation, programming operation or erase operation. For example, AMPI read operations are executed on the plurality of first memory planes to improve parallel read performance of the memory device 104. In some other examples, the address information of target dies may be sent to the memory device 104 along with the first operation command.

In some implementations, the memory controller 106 is further configured to sum the number of the first memory plane and a value of the priority contained in each selected die to get an enable factor; and select the selected dies with larger enable factors as target dies according to an order from large to small of the plurality of enable factors.

In some implementations, the memory controller 106 is further configured to arbitrarily determine at least one selected die from a plurality of selected dies with equal enable factors as the target dies in response to a plurality of equal enable factors.

Referring to FIG. 9, in the it priority setting, the first selected die 111 includes 6 first memory planes with a C value of 6, a priority P of 0 and an enable factor of 6+0, namely 6. The second selected die 112 includes 5 first memory planes and 1 second memory plane with a C value of the sum of bit 1 of the first memory plane and the bit 0 of the second memory plane, namely 5; a priority P of 0, and an enable factor of 5. The third selected die 113 includes 6 first memory planes with a C value of 6, a priority P of 0 and an enable factor of 6. The fourth selected die 114 includes 4 first memory planes and 2 second memory planes with a C value of 4, a priority P of 0 and an enable factor of 4.

In the four selected dies 110, the enable factors are 6, 5, 6, and 4 in turn. At this time, the peak power consumption of the memory system 102 allows 2 dies to execute operations simultaneously. It is possible to select 2 or 1 die with larger enable factors as target dies for operations, for example, selecting the first selected die 111 and the third selected die 113 as target dies. The memory controller 106 sends the first operation command to the memory device 104. The memory device 104 receives the first operation command and executes corresponding operations on the first memory planes in the first selected die 111 and the first memory planes in the third selected die 113 in response to the first operation command. It is noted that two enable factors 6 occur in the present implementation and thus the first selected die 111 and the third selected die 113 corresponding to the two enable factors 6 are both selected as target dies. If there are three enable factors 6, any two selected dies are selected as target dies from the selected dies corresponding to the three enable factors 6.

In some implementations, the memory device 104 is configured to receive the first operation command and execute corresponding operations on the first memory planes in the target dies in response to the first operation command.

In some implementations, the memory controller 106 is further configured to reduce the priority of at least one target die in response to the target dies having executed corresponding operations on the first memory planes contained therein. In implementations of the present disclosure, considering the first selected die 111 as an example, different labels are used in FIG. 9 to facilitate distinguishing selected dies and target dies. For example, the first selected die 111A is not selected as target die, and the first selected die 111B is selected as target die. It is only used to distinguish state change of a selected die on which operations have been executed and not executed.

Referring to FIG. 9, in the i+1^{th} priority setting, the first selected die 111A will be selected or enabled to be the target die on which operation will be executed. The priority of the first selected die 111B will be decreased by 1 after operation has been executed on their first memory planes and the updated priority is −1. There are still operations to be executed for each memory plane after an operation or a cycle of operations has been executed in the first selected die 111B, and the number of the first memory plane is not changed, still being 0. The second selected die 112A is not selected as a target die. At this time, a second memory plane in the second selected die 112A is updated as a first memory plane due to the new incoming operation request. The number of current first memory planes is updated to 6 without changing the priority. The third selected die 111B is selected as the target die on which operations will be executed. The priority of the third selected die 113B will be decreased by 1 after the operation has been executed on their first memory planes and the updated priority is −1. There are still operations to be executed for each memory plane after the current operations have been executed in the third selected die 113B, and the number of first memory planes is not changed. The fourth selected die 114 is not selected as a target die. At this time, a second memory plane in the fourth selected die 114 is updated as first memory plane due to the new incoming operation request. The number of current first memory planes is updated to 5 without changing the priority of 0.

After the i+1^{th} priority setting or updating, the enable factor of the first selected die 111B is 5, the enable factor of the second selected die 112A is 6, the enable factor of the third selected die 113B is 5 and the enable factor of the fourth selected die 114B is 5. The two dies with the largest enable factors are selected as target dies for operation. The second selected die 112A will be selected as the target die. The first selected die 111B, the third selected die 113B and the fourth selected die 114A have equal enable factors. Arbitrary one, for example, the third selected die 113B is selected as the target die.

In the i+2^{th} priority setting, after the first selected die 111B is selected as the target die for operation, 1 is subtracted from the priority, the priority is updated as −2 and the enable factor is 4. After the second selected die 112B is selected as the target die for operation, 1 is subtracted from the priority, the priority is updated as −1 and the enable factor is 5. The third selected die 113A is not selected as the target die with the priority still being −1 and the enable factor being 5. The fourth selected die 114A is not selected as the target die with the priority still being 0 and the enable factor being 5. In the last operation, any two of the second selected die 112B, the third selected die 113A and the fourth selected die 114A may be selected as target dies.

In some implementations, the memory controller 106 is further configured to record the duration for which operation is not executed on each selected die in the plurality of selected dies; and increase the priority of the selected die by at least one in response to the idle duration of one of the selected dies being greater than or equal to a preset duration.

Referring to FIG. 9, in the j^{th} priority setting operation, the fourth selected die 114A is not selected as the target die for a plurality of times. The duration for which operation is not executed on the fourth selected die 114A is long. When it is greater than or equal to the preset duration, if the fourth selected die 114A is not selected as the target die in the i^{th} to the j^{th} priority settings and the duration is greater than or equal to the preset duration, the priority of the fourth die 110A is increased from level 0 to 1 for the j^{th} setting. The j^{th} may be the i+3^{th}.

In the implementations of the present disclosure, j is greater than i+2. The value of j is not limited. Any time the priority of a selected die is updated, if the duration for which operation is not executed on a selected die is greater than or equal to the preset duration, the priority of the selected die is increased by 1, thereby reducing occasions in which certain die is not operated for a long time due to a too low priority and data cannot be fed back to host 108 in time and improving operation speed of the memory system 102 and the user experience. The idle duration mentioned in the implementation may be the duration for which read or write operation is not executed on the selected die, or the duration for which no operation command, no read or written data is sent via the IO interface between the selected die and the memory controller 106. The preset duration may be a set value tested in the ex-factory test of the memory system 102 or the memory device 104 and is stored in a certain storage region in the memory device 104 to be invoked by the memory controller 106.

Specifically, in the j^{th} priority setting operation, the enable factor of the first selected die 111A is 4, the enable factor of the second selected die 112A is 5 and the enable factor of the third selected die 113A is 5. The enable factor of the fourth selected die 114A is increased from 5 to 6 since the priority is increased by one level. If the priority of the fourth selected die 114A is not increased by one level, any two of the second selected die 112A, the third selected die 113A and the fourth selected die 114A are selected as target dies and the third selected die 113A may not be selected. After the priority of the fourth selected die 114A is increased by one level, the fourth selected die 114A is selected as the target die for operation, and any one of the second selected die 112A and the third selected die 113A is selected as the target die for operation.

In the j+1^{th} priority setting operation, no operation is executed on the first selected die 111A with the priority unchanged; no operation is executed on the second selected die 112A with the priority unchanged; and operations are executed on the third selected die 113B with the priority decreased by one level to −2; and operations are executed on the fourth selected die 114B with the priority decreased by one level to 0.

In some implementations, it is possible to determine the number of levels to be increased according to the length of the idle duration. For example, one level is increased in a short idle duration interval, and two levels are increased in a long idle duration interval. In some other implementations, there are more selected dies to be set with priorities, and the priority level setting interval is greater than [−2,2] as shown in FIG. 9. It is possible to increase two or more levels for selected dies with idle durations greater than or equal to the preset duration such that they are selected as target dies for operation.

In some implementations, the memory controller 106 is further configured to determine a maximum number of the target dies according to the peak power consumption allowed currently by the memory system 102.

The peak power consumption allowed currently by the memory system 102 may be determined depending on the current temperature of the memory system 102. In case of high temperature, the allowed peak power consumption is low to guarantee stable operation of the memory system, and in case of low temperature, the allowed peak power consumption may be high. The temperature of the memory system 102 may be obtained by the temperature sensing module integrated in the memory system 102 or obtained by the temperature sensing module outside of the memory system 102. Calculation cores such as the memory controller 106 or the host 108 calculates the peak power consumption according to the current temperature. The memory controller 106 obtains the number of target dies on which operations may be executed in parallel by calculating according to the current peak power consumption or obtains a maximum number of the target dies by accessing a mapping table in which peak power consumptions correspond to the number of target dies. Illustratively, the number of target dies on which operations may be executed in parallel allowed by the current peak power consumption of the memory system 102 shown in FIG. 9 is 2. AMPI read operations may be executed in parallel on the 2 dies 110.

In some implementations, the memory planes without operations to be executed in the plurality of memory planes serve as second memory planes. The memory controller 106 is further configured to acquire the number of the second memory plane in each selected die 110; and adjust the priority of the selected die corresponding to zero second memory plane to the initial priority in response to the number of the second memory plane being zero. The value of the initial priority is the set value acquired upon powering up the memory system 102.

In some implementations, the initial priority is 0.

In some implementations, when there are many selected dies 110 in which all memory planes are first memory planes, the difference between enable factors of the individual selected dies 110 is small. There might be a case in which operations are executed contiguously for a long time on a selected die 110 and some selected dies 110 are idle for a long time. It is possible to adjust the priority of one selected die 110 to the initial 0, thereby increasing difference among enable factors and reducing the cases in which selected dies are idle for a long time.

In some implementations, the memory controller 106 is further configured to: in response to the number of the first memory plane in the selected die 110 being zero, adjust priority of the selected die 110 corresponding to zero first memory plane to the lowest priority; or label the selected die 110 corresponding to zero first memory plane as unselected. The selected die 110 that is labeled as unselected will not be assigned with a priority any longer when no first memory plane is added and will not be operated as the selected die 110.

In some implementations, the memory controller 106 is further configured to adjust the priority of the selected die 110 corresponding to zero first memory plane to 0 level in response to the number of the first memory plane in the selected die 110 being zero. In some other implementations, if the priority of a selected die 110 is 0 level and the number of the first memory plane is 0, the selected die 110 will not be assigned with a priority any longer and will not be operated as the selected die 110.

In some implementations, the memory device 104 is configured to execute asynchronous multi-plane independent AMPI read operation on the first memory planes in the target die in response to the first operation command. Referring to FIG. 9, when any two target dies are selected for implementing AMPI read operation, read operations are executed concurrently and in parallel on first memory planes in each target die, thereby improving the parallel operating efficiency of the memory device 104. The first operation command may include flag information in response to which the memory device 104 starts the AMPI read operation mode.

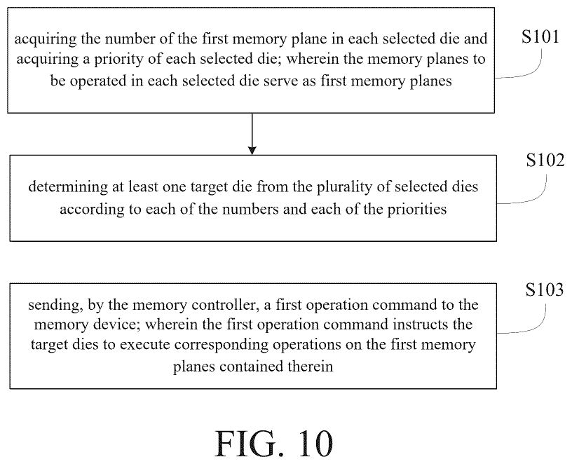

According to the some aspects of the implementations of the present disclosure, FIG. 10 provides a method of operating a memory system, including: acquiring the number of the first memory plane in each selected die and acquiring the priority of each selected die, determining at least one target die from the plurality of selected dies according to each of the numbers and each of the priorities; and sending a first operation command to the memory device by the memory controller. The memory planes to be operated in each selected die serves as first memory planes. The first operation command instructs the target dies to execute corresponding operations on the first memory planes contained therein.

In some implementations, the determining at least one target die from the plurality of selected dies 110 according to each of the numbers and each of the priorities includes: summing the number of the first memory plane and a priority value contained in each selected die 110 to get an enable factor; and selecting the selected dies 110 with larger enable factors as target dies according to an order from large to small of the plurality of enable factors.

In some implementations, the method further includes: arbitrarily determining at least one die 110 from the plurality of selected dies 110 with equal enable factors as the target dies in response to a plurality of equal enable factors.

In some implementations, the method further includes: receiving, by the memory device 104, the first operation command and executing corresponding operations on the first memory planes in the target dies in response to the first operation command.

In some implementations, the acquiring the number of the first memory plane in each selected die 110 includes: acquiring a bit mapping table of the selected dies 110, each bit in the bit mapping table corresponding to one memory plane in the plurality of memory planes and a bit information on the bit indicating whether the memory plane is a first memory plane; and determining the number of bits on which the bit information is a first information according to the bit mapping table. The number of bits on which the bit information is the first information is the number of first memory planes in the plurality of memory planes.

In some implementations, the method further includes: reducing the priority of the at least one target dies in response to the target dies having executed corresponding operations on the first memory planes contained therein.

In some implementations, the method further includes: recording the duration for which operation is not executed on each selected die 110 in the plurality of selected dies 110; and increasing the priority of a selected die by at least one in response to the duration for which no operation is executed on the selected die 110 being greater than or equal to a preset duration.

In some implementations, the method further includes: determining a maximum number of the target dies according to the peak power consumption allowed currently by the memory system 102.

In some implementations, the memory planes without operations to be executed in the plurality of memory planes serve as second memory planes; and the method further includes: acquiring the number of the second memory plane in each selected die 110; and adjusting the priority of the selected die corresponding to zero second memory plane to an initial priority in response to the number of the second memory plane being zero; a value of the initial priority being a set value acquired upon powering up the memory system 102.

In some implementations, the value of the initial priority is 0.

In some implementations, the method further includes: executing, by the memory device 104, asynchronous multi-plane independent AMPI read operation on the first memory planes in the target dies in response to the first operation command.

According to some aspects of an implementation of the present application, there is provided a readable storage medium storing therein a computer program that, when it is executed, implements the method.

The memory device 104 may include a NAND memory. A memory cell of the NAND memory may be a memory cell of a floating-gate type that includes floating-gate transistors or a memory cell of a charge trapping type that includes charge trapping transistors.

The memory medium may be a ferroelectric random access memory (FRAM), a magnetic random access memory (MRAM), a read only memory (ROM), a programmable read-only memory (PROM), an erasable programmable read-only memory (EPROM), an electrically erasable programmable read-only memory (EEPROM), a flash memory, a magnetic surface memory, an optical disk, or a compact disc read-only memory (CD-ROM), and may also be apparatuses including any one or any combination of the above-described memory devices 104.

In some implementations, the executable instructions may be in the form of programs, software, software modules, scripts or codes and may be programed in any form of programming languages including compiled or interpreted language or declarative or procedural language. They may be deployed in any form, including being deployed as stand-alone programs or modules, assemblies, subroutines or other units suitable for using in computing environment.

As an example, the executable instructions may, but not necessarily correspond to files in a file system, may be stored in a part of the file storing other programs or data. For example, they are stored in one or more scripts in a HTML (Hyper Text Markup Language) document, in a single file dedicated to the discussed program, or in a plurality of cooperative files such as a file storing one or more modules, sub-programs or code segments.

As an example, the executable instructions may be deployed to be executed on an electronic apparatus or on a plurality of electronic apparatuses located at a place or on a plurality of electronic apparatuses distributed at a plurality of places and interconnected via communication network.

What have been described above are only implementations of the present disclosure. However, the scope of the present disclosure is not limited thereto, and variations or substitutions that easily occur to one skilled in the art in the scope disclosed in the present disclosure should be encompassed in the scope of the present disclosure.

What is claimed is:

1. A memory system, comprising:
a memory device, the memory device comprising selected dies, each selected die comprising memory planes; wherein a memory plane to be operated in the memory planes serves as first memory plane and the selected dies are at least a plurality of dies among all dies of the memory device; and
a memory controller coupled to the memory device, wherein the memory controller is configured to:
acquire a number of a first memory plane in each selected die and acquire a priority of each selected die;
determine at least one target die from the selected dies according to the number of the first memory plane in each selected die and the priority of each selected die; and
send a first operation command to the memory device; wherein the first operation command indicates the at least one target die to execute corresponding operations on the first memory plane contained therein.

2. The memory system of claim 1, wherein the memory controller is further configured to:
sum the number of the first memory plane in each selected die and a value of the priority of each selected die to get an enable factor; and
select the selected dies with larger enable factor as the at least one target die according to an order from large to small of enable factors.

3. The memory system of claim 2, wherein the memory controller is further configured to:
arbitrarily determine at least one selected die from the selected dies with equal enable factors as the at least one target die in response to equal enable factors.

4. The memory system of claim 1, wherein the memory device is configured to:
receive the first operation command; and
execute the corresponding operations on the first memory plane in the at least one target die in response to the first operation command.

5. The memory system of claim 1, wherein the memory controller is further configured to:
acquire a bit mapping table of the selected dies, each bit in the bit mapping table corresponding to one memory plane in the memory planes and a bit information on the bit indicating whether the memory plane is the first memory plane; and
determine a number of bits on which the bit information is first information according to the bit mapping table; wherein the number of bits on which the bit information is the first information is the number of the first memory plane in the memory planes.

6. The memory system of claim 1, wherein the memory controller is further configured to:
reduce the priority of the at least one target die in response to the at least one target die having executed the corresponding operations on the first memory plane contained therein.

7. The memory system of claim 1, wherein the memory controller is further configured to:
record a duration for which no operation is executed on each selected die in the selected dies; and
increase the priority of the selected die by at least one in response to an idle duration of the selected die being greater than or equal to a preset duration.

8. The memory system of claim 1, wherein the memory controller is further configured to:
determine a maximum number of the at least one target die according to a peak power consumption allowed currently by the memory system.

9. The memory system of claim 1, wherein a memory plane without operations to be executed in the memory planes serves as second memory plane; and the memory controller is further configured to:
acquire a number of the second memory plane in each selected die; and
adjust the priority of the selected die corresponding to zero second memory plane to an initial priority in response to the number of the second memory plane being zero, wherein a value of the initial priority is a set value acquired upon powering up the memory system.

10. The memory system of claim 9, wherein the value of the initial priority is 0.

11. The memory system of claim 4, wherein the memory device is further configured to:
execute asynchronous multi-plane independent AMPI read operation on the first memory plane in the at least one target die in response to the first operation command.

12. A method of operating a memory system, comprising:
acquiring a number of a first memory plane in each selected die of a memory device and acquiring a priority of each selected die; wherein a memory plane to be operated in each selected die serves as the first memory plane;
determining at least one target die from selected dies of the memory device according to the number of the first memory plane in each selected die and the priority of each selected die; and
sending, by a memory controller, a first operation command to the memory device; wherein the first operation command indicates the at least one target dies to execute corresponding operations on the first memory plane contained therein.

13. The method of claim 12, wherein the determining of the at least one target die from the selected dies comprises:
summing the number of the first memory plane in each selected die and a value of the priority of each selected die to get an enable factor; and
selecting the selected dies with larger enable factor as the at least one target die according to an order from large to small of enable factors.

14. The method of claim 13, wherein the method further comprises:
arbitrarily determining at least one selected die from of the selected dies with equal enable factors as the at least one target die in response to equal enable factors.

15. The method of claim 12, wherein the method further comprises:
receiving, by the memory device, the first operation command, and
executing the corresponding operations on the first memory plane in the at least one target die in response to the first operation command.

16. The method of claim 12, wherein the acquiring of the number of the first memory plane in each selected die comprises:
acquiring a bit mapping table of the selected dies, each bit in the bit mapping table corresponding to one memory plane in the memory planes and a bit information on the bit indicating whether the memory plane is a first memory plane; and
determining a number of bits on which the bit information is a first information according to the bit mapping table; wherein the number of bits on which the bit information is the first information is the number of the first memory plane in the memory planes.

17. The method of claim 12, wherein the method further comprises:
reducing the priority of the at least one target die in response to the at least one target die having executed the corresponding operations on the first memory plane contained therein.

18. The method of claim 12, wherein the method further comprises:
recording a duration for which no operation is executed on each selected die in the selected dies; and
increasing the priority of a selected die by at least one in response to the duration for which no operation is executed on the selected die is greater than or equal to a preset duration.

19. The method of claim 12, wherein the method further comprises:
determining a maximum number of the at least one target die according to a peak power consumption allowed currently by the memory system.

20. A readable storage medium storing therein a computer program that, when it is executed, implements a method of operating a memory system comprising:
acquiring a number of a first memory plane in each selected die of a memory device and acquiring a priority of each selected die; wherein a memory plane to be operated in each selected die serves as the first memory plane;
determining at least one target die from selected dies of the memory device according to the number of the first memory plane in each selected die and the priority of each selected die; and
sending, by a memory controller, a first operation command to the memory device; wherein the first operation command indicates the at least one target dies to execute corresponding operations on the first memory plane contained therein.
